(19) United States
(12) Patent Application Publication
(10) Pub. No.: US 2007/0072426 A1
(43) Pub. Date: Mar. 29, 2007

(54) CHEMICAL MECHANICAL POLISHING PROCESS AND APPARATUS THEREFOR

(76) Inventors: Tzu-Yu Tseng, Kaohsiung City (TW); Chun-Ting Hu, Hsinchu City (TW); Chu-Yi Hsieh, Hsinchu City (TW); Hung-Chi Pai, Nantou County (TW); Yung-Chieh Kuo, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,856

(22) Filed: Sep. 26, 2005

(51) Int. Cl. C03C 15/00; H01L 21/461; H01L 21/306; C23F 1/00

(52) U.S. Cl. 438/692; 156/345.12; 216/88

(57) ABSTRACT

A CMP process and a CMP apparatus therefor are provided. First, a substrate including a semiconductor structure, a liner layer over the semiconductor structure and a metal layer over the liner layer is provided. Next, a metal polishing step is performed to polish the metal layer until a portion of the liner layer is exposed. Next, a buffing step is performed to remove any contaminants from the surface of the metal layer. Thereafter, a liner CMP step is performed to polish the liner layer.

### BACKGROUND OF THE INVENTION

1. Field of the Invention

The present invention is generally related to a chemical mechanical polishing (CMP) process and an apparatus thereof. More particularly, the present invention relates to a CMP process with high uniformity and low contamination and an apparatus thereof.

2. Description of Related Art

Recently, as the IC industry advances, the manufacturing of wafer has developed towards higher density, greater integration and excellent performance. In order to increase the density and the number of conductive wire layers of the IC, a global planarization process is essential. Conventionally, the global planarization process is implemented by the chemical mechanical polishing (CMP) technology.

In general, the CMP process is performed for planarizing a layer deposited on a patterned layer or a structure. For example, in a process of manufacturing a shallow trench isolation (STI) structure, first, a shallow trench is formed in a substrate. Next, a silicon nitride layer and a liner layer are sequentially formed over the wall of the trench structure. Thereafter, a silicon oxide layer is formed over the substrate filling the trench structure. Thereafter, a CMP process is performed to planarize the surface of the silicon oxide layer.

Similarly, in a process of manufacturing a metal layer structure, first, a semiconductor structure, for example, a contact hole or a via hole, is formed in a substrate, and then a barrier layer are formed on the sidewall of the semiconductor structure. Thereafter, a metal layer is formed over the substrate filling the semiconductor structure. Thereafter, a CMP process is performed to planarize the surface of the metal layer.

However, poor quality of CMP process will invariably lead to a variety of problems, for example, the distribution of the height of the polished layer is not uniform. Moreover, the surface of the polished layer may be contaminated by the residues of slurry, polishing pad or polished layer. In addition, some byproducts such as metal oxides due the reaction between the solution of slurry and the metal layer may remain on the surface of the polished layer after the CMP process.

Therefore there is a need for improving a CMP process that is capable of polishing a surface with high uniformity and reducing the contamination of the polished surface in order to increase the reliability of the semiconductor device. Preferably such improved process should be part of the standard CMP process as currently used, thus being able to have a minimum impact the existing manufacturing process.

### SUMMARY OF THE INVENTION

Accordingly, the present invention is directed to a CMP process capable of polishing a surface with high uniformity and reducing contamination on the polished surface.

The present invention is also directed to an apparatus for performing the above-mentioned CMP process.

According to one embodiment of the present invention, the CMP process comprises, for example but not limited to, the following steps. First, a substrate comprising a semiconductor structure, for example, a contact hole, a via hole, a trench, a single damascene opening or a dual damascene opening, or the like, a liner layer over the semiconductor structure and a metal layer over the liner layer covering the semiconductor structure. Next, the resulting structure is loaded into a first module of the CMP apparatus and a metal polishing step is performed to polish the metal layer until a portion of the liner layer exposed. Next, the substrate is transferred from the first module to a second module, where a buffing step is performed further polish the polished surface to reduce contamination thereon. Thereafter, the substrate is transferred from the second module to a third module, where a liner polishing step is performed to polish the liner layer.

In one embodiment of the present invention, the metal layer comprises a copper (Cu) layer or a tungsten (W) layer.

In one embodiment of the present invention, the liner layer comprises a titanium nitride (TiN) liner layer or a tantalum nitride (TaN) liner layer.

In one embodiment of the present invention, the first module, the second module or the third module comprises a single process chamber.

In one embodiment of the present invention, the first module, the second module or the third module comprises a plurality of process chambers.

In one embodiment of the present invention, the buffing step comprises the steps of immersing the substrate in a solution, and polishing polished surface with a buffing pad.

In one embodiment of the present invention, the solution comprises deionized water (DI water).

In one embodiment of the present invention, the solution comprises cleaning solution of CO₂ water, or amine base chemical solution.

According to one embodiment of the present invention, the CMP apparatus comprises, for example but not limited to, a first module is adapted for carrying out a metal polishing step to polish the metal layer, a second module is adapted for carrying out a buffing step to remove any contaminants from the surface of the metal layer and thereby reduce the contamination, and a third module is adapted for carrying out a liner polishing step to polish the liner layer, wherein the buffing step is performed after performing the metal polishing step.

In one embodiment of the present invention, the metal layer comprises a copper (Cu) layer or a tungsten (W) layer.

In one embodiment of the present invention, the liner layer comprises a titanium nitride (TiN) liner layer or a tantalum nitride (TaN) liner layer.

In one embodiment of the present invention, the first module, the second module or the third module comprises a single process chamber.

In one embodiment of the present invention, the first module, the second module or the third module comprises a plurality of process chambers.

In one embodiment of the present invention, the buffing step comprises the steps of immersing the substrate in a solution, and polishing a surface of the substrate with a buffing pad.

In one embodiment of the present invention, the solution comprises deionized water (DI water).

In one embodiment of the present invention, the solution comprises cleaning solution of CO₂ water, or amine base chemical solution.

According to one embodiment of the present invention, the CMP process comprises, for example but not limited to, the following steps. First, a substrate comprising a semiconductor structure, a liner layer over the semiconductor structure and a metal layer over the liner layer covering the semiconductor structure is provided. Next, a metal polishing step is performed to polish the metal layer until a portion of the liner layer is exposed. Next, a buffing step is performed to remove any contaminant on the polished surface and thereby reduce the contamination. Thereafter, a liner polishing step is performed to polish the liner layer.

In one embodiment of the present invention, the metal layer comprises a copper (Cu) layer or a tungsten (W) layer.

In one embodiment of the present invention, the liner layer comprises a titanium nitride (TiN) liner layer or a tantalum nitride (TaN) liner layer.

In one embodiment of the present invention, the buffing step comprises the steps of immersing the substrate in a solution, and polishing a surface of the substrate with a buffing pad.

In one embodiment of the present invention, the solution comprises deionized water (DI water).

In one embodiment of the present invention, the solution comprises cleaning solution of CO₂ water, or amine base chemical solution.

Accordingly, the buffing step is applied for removing any contaminants from the surface of the wafer, the possibility of contaminations on the wafer surface can be effectively. In addition, the uniformity of the surface of the polished substrate can be effectively improved by subjecting the substrate to the CMP process of the present invention.

One or part or all of these and other features and advantages of the present invention will become readily apparent to those skilled in this art from the following description wherein there is shown and described a preferred embodiment of this invention, simply by way of illustration of one of the modes best suited to carry out the invention. As it will be realized, the invention is capable of different embodiments, and its several details are capable of modifications in various, obvious aspects all without departing from the invention. Accordingly, the drawings and descriptions will be regarded as illustrative in nature and not as restrictive.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are schematic cross-sectional views illustrating the progressive steps of a CMP process for fabricating a semiconductor structure according to one embodiment of the present invention.

FIG. 2 is a schematic top view of a CMP apparatus according to one embodiment of the present invention.

### DESCRIPTION OF EMBODIMENTS

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

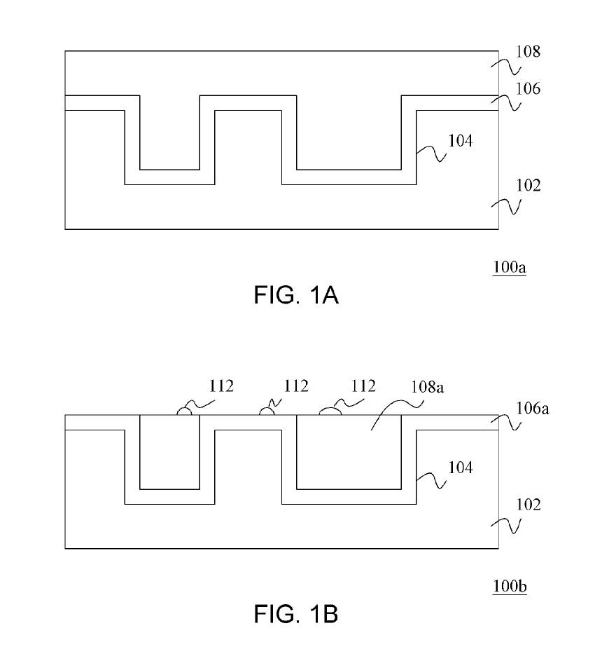

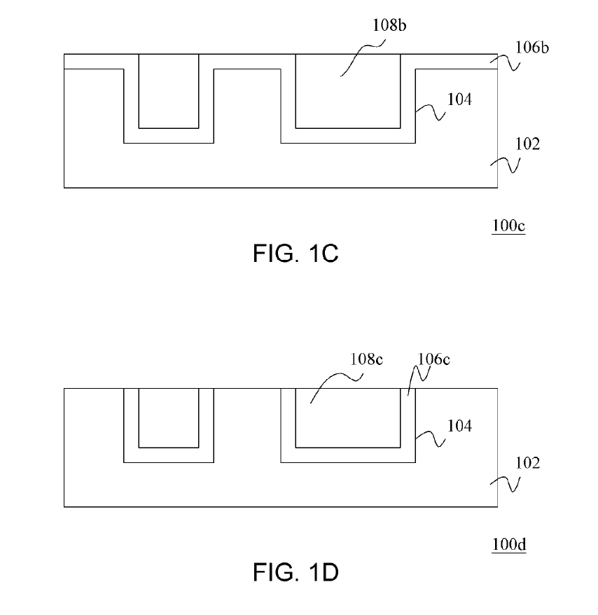

FIG. 1A to FIG. 1D are schematic cross-sectional views illustrating the progressive steps of a CMP process for fabricating a semiconductor structure according to one embodiment of the present invention. Referring to FIG. 1A, a wafer 100a comprising a substrate 102, a semiconductor structure 104 formed in the substrate 102, a liner layer 106 formed over the semiconductor structure 104 and a metal layer 108 over the liner layer 106 covering the semiconductor structure 104. The semiconductor structure 104 comprises, for example but not limited to, a trench, a via hole, a contact hole or a single damascene opening or dual damascene opening, or the like. The material of the semiconductor structure 104 comprises, for example but not limited to, dielectric material. The liner layer 106 comprises, for example but not limited to, a titanium nitride (TiN) liner layer or a tantalum nitride (TaN) liner layer. The metal layer 108 comprises, for example but not limited to, a copper (Cu) layer or a tungsten (W) layer. The liner layer 106 and the metal layer 108 may be formed by, for example but not limited to, chemical vapor deposition (CVD) method or physical vapor deposition method (PVD). It should be noted that even though the surface of the wafer 100a in FIG. 1A is illustrated to have planarized topography, however, one skilled in the art will understand that the surface of the structure is rough due to poor step coverage due to the presence of the semiconductor structure 104 in the substrate 102.

Thereafter, a metal polishing step is carried out to polish the metal layer 108 until a portion of the liner layer 106 is exposed to obtain a wafer 100b illustrated in FIG. 1B. As shown in FIG. 1B, after the metal polishing process, contaminants 112 may be present on the surface of the wafer 100b as contamination. The contaminants 112 may be, for example but not limited to, residual particles or solution of the slurry, or the residues of the polish pad used in the metal polishing step. Furthermore, the contaminants 112 may be, for example but not limited to, byproducts resulting from chemical reactions during the metal polishing step. The byproducts comprise, for example but not limited to, oxides due to reaction between the metal layer 108 and the slurry solution.

Thereafter, as shown in FIG. 1C, a buffing step is carried out to remove the contaminants 112 from the surface of the wafer 100b. In one embodiment of the present invention, the buffing step comprises, for example, immersing the wafer 100b in a solution. The solution comprises, for example but not limited to, deionized water (DI water) or other cleaning solution of CO₂ water, or amine base chemical solution. In addition, the surface of the wafer 100b may be polished by using a buffing pad. After the buffing step, a wafer 100c is obtained

Thereafter, as shown in FIG. 1C, the surface of the wafer 100c is cleaned. Next, referring to FIG. 1D, a liner polishing step is carried out to polish the liner layer 106b. In one embodiment of the present invention, the liner polishing step is continued until a portion of the semiconductor structure 104 is exposed. It should be noted that, because the buffing step is applied for removing contaminants 112 from the surface of the wafer 100c, the possibility of the contaminations on the surface of the wafer 100d is reduced during the liner polishing step. In addition, the CMP process of the present invention is capable of improving the uniformity of the surface of the wafer.

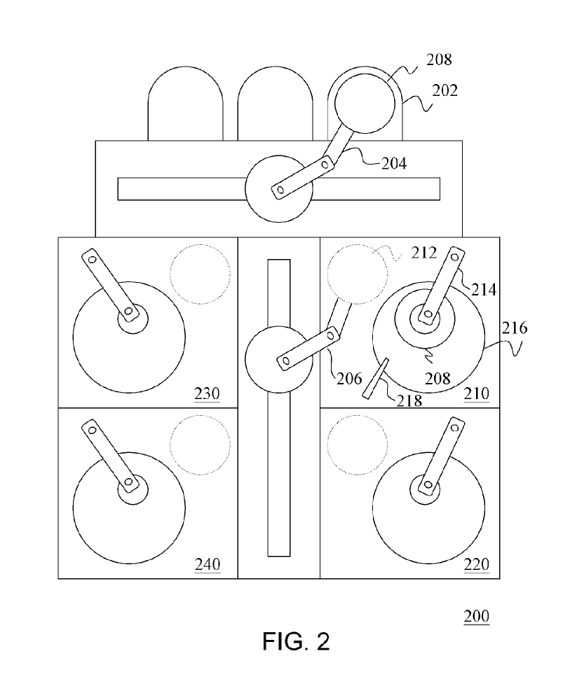

FIG. 2 is a schematic top view of a CMP apparatus according to one embodiment of the present invention. Hereinafter, the CMP apparatus 200 and the CMP process using the CMP apparatus 200 will be described. Referring to FIG. 2, the apparatus 200 comprises, for example but not limited to, a storage pod 202, wafer loaders 204 and 206 and a plurality of process modules 210, 220, 230 and 240. It should be noted that, even though the number of the modules shown in FIG. 2 is 4, however, the apparatus 200 of the present invention may comprise any number of modules. In addition, each module may comprise one or more process chambers even though each of the modules 210, 220, 230 and 240 shown in FIG. 2 comprises one process chamber respectively. Each of the modules 210, 220, 230 and 240 may comprise, for example but not limited to, a position 212, a wafer loader 214, a polish pad 216 and a slurry dispenser 218. The storage pod 202 is provided for loading the pod of the wafer(s) 208. The wafer loader 204 is provided for loading the wafer 208 from the storage pod 202, and the wafer loader 206 is provided for loading the wafer 208 to the position 212. The wafer loader 214 is provided for loading the wafer 208 from the position 212, and polishing the surface of the wafer 208 on the polish pad 216 by holding the active surface of the wafer 208 against the polish pad 216. The slurry dispenser 218 is used for supplying the slurry to the surface of the polish pad 216, and another pipeline (not shown) may also be adopted for supplying the clean solution such as the deionized water (DI) water to the surface of the polish pad 216.

Referring to FIG. 2, the CMP apparatus 200 may be utilized to carryout the process described with reference to FIG. 1A to FIG. 1D. First of all, a wafer 100a shown in FIG. 1A may be loaded into the first module of the CMP apparatus 200. Next, the metal polishing step is carried out to polish the metal layer 108 of the wafer 100a to obtain the wafer 100b. Thereafter, the wafer 100b may be transferred to the second module of the CMP apparatus 200 where the wafer 100b is subjected to the buffing step to remove any contaminants the surface of the wafer 100b, and obtain the wafer 100c. Thereafter, the wafer 100c may be transferred to the third module of the CMP apparatus 200 where the liner polishing step is carried out to polish the liner layer 106b. In one embodiment of the present invention, during the liner polishing step may be continued until a portion of the semiconductor structure 104 is exposed.

Accordingly, because the buffing step applied for removing any contaminants from the surface of the wafer 100b, the contaminations on the surface of the wafer is effectively. In addition, the uniformity of the surface of the wafer 100d obtained after the liner polishing step is effectively improved.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A chemical mechanical polishing (CMP) process, comprising:
providing a substrate comprising a semiconductor structure, a liner layer over the semiconductor structure and a metal layer over the liner layer covering the semiconductor structure;
transferring the substrate into a first module and performing a metal polishing step to polish the metal layer until a portion of the liner layer is exposed;
transferring the substrate from the first module to a second module;
performing a buffing step in the second module to remove any contaminants from a surface of the metal layer;
transferring the substrate from the second module to a third module; and
performing a liner polishing step in the third module to polish the liner layer.

2. The CMP process of claim 1, wherein the metal layer comprises a copper (Cu) layer or a tungsten (W) layer.

3. The CMP process of claim 1, wherein the liner layer comprises a titanium nitride (TiN) liner layer or a tantalum nitride (TaN) liner layer.

4. The CMP process of claim 1, wherein the first module, the second module or the third module comprises a single process chamber.

5. The CMP process of claim 1, wherein the first module, the second module or the third module comprises a plurality of process chambers.

6. The CMP process of claim 1, wherein the buffing step comprises:
immersing the substrate in a solution; and
polishing a surface of the substrate with a buffing pad.

7. The CMP process of claim 6, wherein the solution comprises deionized water (DI water) or a cleaning solution of CO₂ water or amine base chemical solution.

8. A chemical mechanical polishing (CMP) apparatus for polishing a substrate comprising a semiconductor structure, a liner layer over the semiconductor structure and a metal layer over the liner layer covering the semiconductor structure, the CMP apparatus comprising:
a first module, for carrying out a metal polishing step to polish the metal layer;
a second module, for carrying out a buffing step to remove any contaminants from a surface of the metal layer; and
a third module, for carrying out a liner polishing step to polish the liner layer, wherein the buffing step is performed after performing the metal polishing step.

9. The CMP apparatus of claim 8, wherein the metal layer comprises a copper (Cu) layer or a tungsten (W) layer.

10. The CMP apparatus of claim 8, wherein the liner layer comprises a titanium nitride (TiN) liner layer or a tantalum nitride (TaN) liner layer.

11. The CMP apparatus of claim 8, wherein the first module, the second module or the third module comprises a single process chamber.

12. The CMP apparatus of claim 8, wherein the first module, the second module or the third module comprises a plurality of process chambers.

13. The CMP apparatus of claim 8, wherein the buffing step comprises:
immersing the substrate in a solution; and
polishing a surface of the substrate with a buffing pad.

14. The CMP apparatus of claim 13, wherein the solution comprises deionized water (DI water), or a cleaning solution of CO₂ water or amine base chemical solution.

15. A chemical mechanical polishing (CMP) process, comprising:
providing a substrate comprising a semiconductor structure, a liner layer over the semiconductor structure and a metal layer over the liner layer covering the semiconductor structure;
performing a metal polishing step to polish the metal layer until a portion of the liner layer is exposed;
performing a buffing step to remove any contaminants from a surface of the metal layer; and
performing a liner polishing step to polish the liner layer.

16. The CMP process of claim 15, wherein the metal layer comprises a copper (Cu) layer or a tungsten (W) layer.

17. The CMP process of claim 15, wherein the liner layer comprises a titanium nitride (TiN) liner layer or a tantalum nitride (TaN) liner layer.

18. The CMP process of claim 15, wherein the buffing step comprises:
immersing the substrate in a solution; and
polishing a surface of the substrate with a buffing pad.

19. The CMP process of claim 18, wherein the solution comprises deionized water (DI water), or a cleaning solution of CO₂ water, or amine base chemical solution.
